(19) United States
(12) Patent Application Publication
(10) Pub. No.: US 2011/0132755 A1
(43) Pub. Date: Jun. 9, 2011

(54) IN-LINE SYSTEM FOR MANUFACTURING SOLAR CELL

(76) Inventors: Woosam KIM, Suwon-city (KR); Youngkun KIM, Suwon-city (KR)

(21) Appl. No.: 12/949,198

(22) Filed: Nov. 18, 2010

(30) Foreign Application Priority Data
Dec. 4, 2009 (KR) 10-2009-0119707
Dec. 4, 2009 (KR) 10-2009-0119710

(51) Int. Cl. C23C 14/34; C23C 14/24; C23C 14/14

(52) U.S. Cl. 204/298.09; 204/298.26; 204/298.13

(57) ABSTRACT

An in-line system for manufacturing a solar cell is provided. The in-line system includes a substrate loading zone for inputting a substrate, a deposition part for sequentially continuously depositing a light absorption layer on a top surface of the substrate, and a thermal processing part for thermally processing the substrate transferred from the deposition part. The substrate loading zone and the thermal processing part are sequentially installed in a partitioned internal space of one integration chamber.

### CROSS REFERENCE

This application claims foreign priority under Paris Convention and 35 U.S.C. §119 to Korean Patent Application No. 10-2009-0119707, filed Dec. 4, 2009, and Korean Patent Application No. 10-2009-0119710, filed Dec. 4, 2009 with the Korean Intellectual Property Office.

### BACKGROUND OF THE INVENTION

1. Field of the Invention

The present invention relates to an in-line system for manufacturing a Copper Indium Gallium (di)-Selenide (CIGS) solar cell. More particularly, the present invention relates to a solar cell manufacturing in-line system for, by sequentially connecting and installing a substrate loading zone, a deposition part, and a thermal processing part within one integration chamber, continuously processing a substrate and also, by isolating an installation space of a sputter unit of the deposition part, not only replacing a sputter target without doing damage to a vacuum state of the whole vacuum chamber but also making controllable a distance between the sputter target and the substrate, reducing a process time, decreasing a length of the whole layout, and making efficient management of a manufacturing line possible.

2. Description of the Related Art

In general, a solar cell, one of semiconductor devices for directly converting light energy into electric energy, is mainly classified into a silicon solar cell such as a polycrystalline and single-crystalline silicon solar cell and an amorphous silicon solar cell, a compound semiconductor solar cell, and the like.

The silicon solar cell is a photovoltaic cell for producing electric energy using the principle of solar electricity generation by a Positive Negative (PN) junction, by processing a silicon wafer, placing an N-type semiconductor and a P-type semiconductor of a different pole in contact with each other, and forming an electrode.

A CIGS solar cell, a compound semiconductor solar cell, is a solar cell having a light absorption layer of a high lightabsorption coefficient composed of copper (Cu), indium (In), gallium (Ga), selenium (Se), etc. and deposited on a substrate such as glass, polymer, etc., and producing electric energy. The CIGS solar cell can be manufactured at high efficiency even with a thin film of a thickness of 1 to 2 μm. Also, because of an excellent electric and optic stability, the CIGS solar cell can form a very ideal light absorption layer. So, the CIGS solar cell is being researched as a solar cell of low price and high efficiency.

Generally, the compound semiconductor solar cell laminate and forms thin film layers such as a rear electrode, a light absorption layer, a buffer layer, a transparent electrode layer, an anti-reflection film, a grid, etc. as one unit thin film on a substrate. So, the compound semiconductor solar cell is manufactured through a plurality of treatment processes such as a sputter deposition process or evaporation deposition process for forming the thin film layers, and the like.

Accordingly, a conventional solar cell manufacturing process uses a plurality of equipments for performing respective processes such as a vacuum chamber for forming the thin film layer, a sputter deposition device, an evaporation deposition device, and the like.

Here, the sputter deposition device deposits a thin film using a sputtering phenomenon of jumping atoms or molecules out of a sputter target surface by accelerating positive ions generated at glow electric discharge with a high energy of high voltage and making the high-energy positive ions collide with the sputter target surface.

Generally, the conventional sputter deposition device installs a sputter unit mounting a sputter target within a vacuum chamber and deposits desired materials on a substrate surface, by applying a Radio Frequency (RF) or Direct Current (DC) high voltage to the sputter target and making positive ions of plasma state collide with the sputter target.

However, a conventional process line for manufacturing a solar cell has the following problems.

The first is that, because the sputter deposition device, the evaporation deposition device, the thermal processing device, and the like are individually installed and a process is carried out in a separate line, a continuity of respective processes is not only deteriorated but also a substrate movement distance increases, a process speed decreases, a process efficiency decreases, and also a process throughput is greatly deteriorated. The second is that, because a plurality of vacuum chambers or thermal processing chambers each are individually provided, it is difficult to make the common use of a like equipment such as a vacuum pump. The third is that, because a layout of a deposition process line is lengthened, an efficient management of a manufacturing line is difficult. The fourth is that, because there is damage to a vacuum atmosphere of the whole vacuum chamber at sputter target replacement, it is impossible to perform the sputter target replacement in course of deposition process performance and in addition, much time and cost are consumed for damaging and again creating a vacuum. The fifth is that, because a spaced distance between a sputter target and a substrate cannot be suitably controlled in accordance with the consumption of the sputter target following the progress of a deposition process, it is difficult to secure a uniform deposition quality.

### SUMMARY OF THE INVENTION

An aspect of exemplary embodiments of the present invention is to address at least the problems and/or disadvantages and to provide at least the advantages described below. Accordingly, an aspect of exemplary embodiments of the present invention is to increase a continuity of processes and simultaneously obtain an increase of process efficiency resulting from process speed improvement, by sequentially connecting and installing a substrate loading zone, a deposition part, and a thermal processing part in line with each other in one integration chamber.

Another aspect of exemplary embodiments of the present invention is to easily make the common use of a like equipment such as a vacuum pump, etc. and reduce an installation cost, by connecting and installing a vacuum chamber or thermal processing, chamber for performing each process.

A further aspect of exemplary embodiments of the present invention is to simplify a layout of a deposition process line and increase a mass productivity through an efficient management of a solar cell manufacturing line.

A yet another aspect of exemplary embodiments of the present invention is to isolate a sputter unit installation space from an internal space of a vacuum chamber, and make sputter target replacement possible without doing damage to a vacuum state of the whole vacuum chamber.

A still another aspect of exemplary embodiments of the present invention is to make it possible to simply and conveniently control a spaced distance between a sputter target and a substrate even in course of a deposition process, and improve deposition quality and process efficiency.

According to one aspect of the present invention, an in-line system for manufacturing a solar cell is provided. The in-line system includes a substrate loading zone for inputting a substrate, a deposition part for sequentially continuously depositing a light absorption layer on a top surface of the substrate, and a thermal processing part for thermally processing the substrate transferred from the deposition part. The substrate loading zone and the thermal processing part are sequentially installed in a partitioned internal space of one integration chamber. Each transfer means transferring the substrate is sequentially connected and installed such that the substrate can be continuously transferred while being processed within one integration chamber.

The transfer means includes conveyor units installed at lower parts of the substrate loading zone, the deposition part, and the thermal processing part, respectively, and being capable of sequentially continuously transferring the substrate.

### BRIEF DESCRIPTION OF THE DRAWINGS

The above and other objects, features and advantages of the present invention will become more apparent from the following detailed description when taken in conjunction with the accompanying drawings in which:

FIG. 1 is a schematic diagram illustrating a construction of an in-line system for manufacturing a solar cell according to the present invention;

FIG. 2 is a schematic diagram illustrating a construction of an evaporation part according to an exemplary embodiment of the present invention;

FIG. 3 is a schematic diagram illustrating an operation state of a sputter part according to the present invention;

FIG. 4 is a flow diagram illustrating an operation of an in-line system for manufacturing a solar cell according to the present invention;

FIG. 5 is a schematic diagram illustrating a construction of a sputter part according to an exemplary embodiment of the present invention;

FIG. 6 is a schematic diagram illustrating a construction of a sputter part with a roll-to-roll unit that is a substrate transfer means; and

FIG. 7 is a diagram illustrating an operation state of the sputter part of FIG. 5.

Throughout the drawings, the same drawing reference numerals will be understood to refer to the same elements, features and structures.

### DETAILED DESCRIPTION OF THE INVENTION

Exemplary embodiments of the present invention will now be described in detail with reference to the annexed drawings. In the following description, a detailed description of known functions and configurations incorporated herein has been omitted for conciseness.

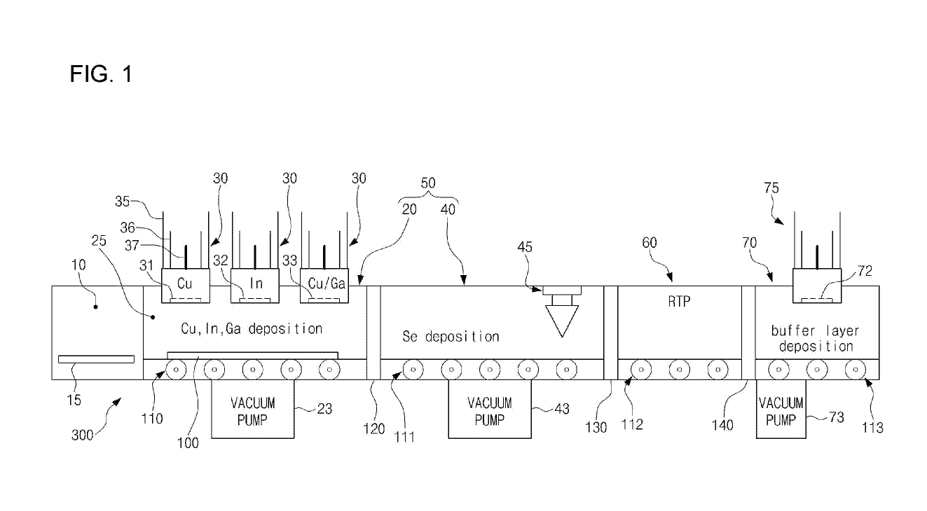

FIG. 1 is a schematic diagram illustrating a construction of an in-line system for manufacturing a solar cell according to the present invention.

The present invention is to laminate and form a light absorption layer of a Copper Indium Gallium (di)-Selenide (CIGS) solar cell on a substrate. The present invention relates to an in-line system for sequentially depositing copper (Cu), indium (In), copper/gallium (Cu/Ga), and a selenide compound on a substrate surface and forming a CIGS thin film that is the light absorption layer of the CIGS solar cell.

As illustrated in FIG. 1, the in-line system according to the present invention includes a substrate loading zone 10, a light absorption layer deposition part 50, and a thermal processing part 60.

The substrate loading zone 10, the deposition part 50, and the thermal processing part 60 are sequentially installed in a partitioned internal space of one integration chamber 300. At this time, the substrate loading zone 10, the deposition part 50, and the thermal processing part 60 are sequentially connected and installed such that transfer means 110, 111, 112, and 113 transferring a substrate 100 can interwork with each other. By doing so, the substrate 100 can be processed while being continuously transferred within one integration chamber 300.

The substrate loading zone 10 is installed at a front end of the integration chamber 300, and plays a role of performing a subsequent process of sequentially inputting the substrate 100 to the deposition part 50.

The substrate loading zone 10 is a part of, by maintaining an internal environment condition at a low vacuum state (about 1.0E-3 Torr), forming a load lock chamber playing a buffer role of buffering a pressure difference impact that the substrate 100 can suffer when the substrate 100 is inputted to the deposition part 50 of an environment condition of a high vacuum (about 1.0E-6 to 1.0E-7 Torr).

A gate valve (not shown) can be installed in a connection part between the substrate loading zone 10 and the deposition part 50, and isolate internal regions of the integration chamber 300 from each other.

The substrate loading zone 10 includes the transfer means transferring the substrate 100 and a vacuum pump (not shown) and also, can include a preheating means 15 capable of previously heating the substrate 100.

The transfer means can be comprised of a plurality of transfer rollers or conveyor units. The preheating means 15 may be comprised of a common heating line capable of heating the substrate 100 at a temperature of about 300° C.

The substrate loading zone 10 can separately install the vacuum pump, but may connect to a vacuum pump 23 installed in a sputter part 20 of the deposition part 50 described below.

The substrate 100 can be of polymer, which is plastic material having flexibility, glass, or metal material such as a Stainless Steel (SUS) plate of a thin plate form.

The deposition part 50 is a part connected and installed in the substrate loading zone 10 and forming a light absorption layer consisting of copper (Cu), indium (In), gallium (Ga), and selenium (Se) on a top surface of the substrate 100. The deposition part 50 includes the sputter part 20 and an evaporation part 40.

The sputter part 20 is a part including a plurality of sputter units 30 of copper (Cu), indium (In), and copper/gallium (Cu/Ga) as sputter targets 31, 32, and 33, respectively. The sputter units 30 are installed at a top of the integration chamber 300, and are spaced apart and arranged to make sequential continuous deposition along a transfer direction of the substrate 100 possible.

The sputter units 30 are each installed to enable the sputter targets 31, 32, and 33 to face the top surface of the substrate 100.

The sputter unit 30 does not limit the sputter targets 31, 32, and 33 to copper (Cu), indium (In), and copper/gallium (Cu/Ga), respectively, but may be a combination of various forms such as Copper-Indium (CI), copper-Indium-Gallium (CIG), etc. by allowing one sputter target to include a combination of the elements.

A power source 37 of the sputter unit 30 can be a DC or RF power source. The sputter targets 31, 32, and 33 each forms a cathode.

A cooling line 35 is installed in the sputter unit 30.

The cooling line 35 can circulate cooling water, thereby cooling the sputter unit 30.

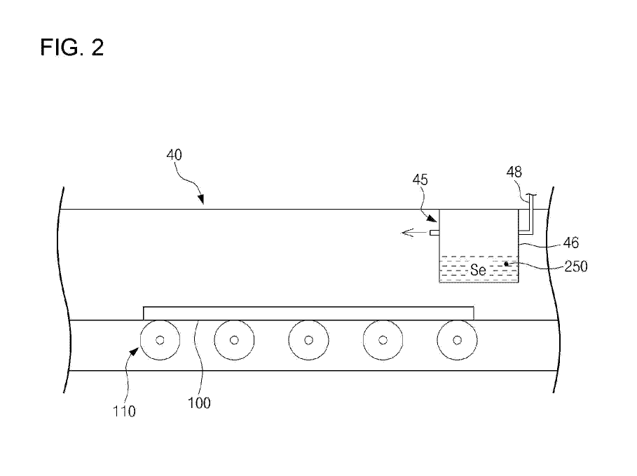

A gas supply line 36 is installed in the sputter unit 30 and supplies an inert gas such as argon (Ar) and forms plasma 200 (shown in FIG. 2) at lower side surfaces of the sputter targets 31, 32, and 33.

In conclusion, the sputter unit 30 sequentially vacuum-deposits copper (Cu), indium (In), and copper/gallium (Cu/Ga) on the top surface of the substrate 100 transferred.

The internal of the sputter part 20 has a vacuum chamber 25 having an atmosphere of high vacuum of about 1.0E-6 to 1.0E-7 Torr. The substrate 100 is transferred by a transfer means 110 installed at a lower side of the vacuum chamber 25.

A vacuum pump 23 is installed at a lower side of the sputter part 20, and forms the vacuum chamber 25 of a high vacuum.

The evaporation part 40 is a part of performing an evaporation deposition process of vacuum-evaporating selenium (Se) particles and depositing selenium (Se) on the top surface of the substrate 100. The evaporation part 40 has a selenium evaporator 45 (using H₂Se, H₂S, etc.) at its upper side, and has a transfer means 111 transferring the substrate 100 at its lower side.

The evaporation part 40 has a vacuum pump 43 for forming an atmosphere of a high vacuum of about 1.0E-6 to 1.0E-7 Torr within the evaporation part 40.

However, the sputter part 20 and the evaporation part 40 may make the common use of one high vacuum pump

FIG. 2 is a schematic diagram illustrating a construction of the selenium evaporator 45 of the evaporation part 40 according to an exemplary embodiment of the present invention. Because of a characteristic of the selenium evaporator 45 evaporating and depositing selenium particles 250 on the substrate 100, the selenium evaporator 45 includes a storage container 46 for containing the selenium particles 250 therein. A common heating means (not shown) can be provided at a lower side of the storage container 46, and heat and evaporate the selenium particles 250 at a predetermined temperature (about 300° C.).

As the heating means, a common heating line can be arranged and installed, but this does not intend to limit the scope of the present invention. That is, a laser may be used for heating and evaporating the selenium particles 250.

Because an evaporated selenium gas moves upwards, the selenium evaporator 45 includes a carrier gas supply line 48 for carrying the evaporated selenium gas to the top surface of the substrate 100.

As indicated by arrow, the carrier gas supply line 48 jets the inert gas such as argon (Ar) together with the evaporated selenium gas such that the selenium gas can be deposited on the top surface of the substrate 100.

A gate valve 120 can be installed between the sputter part 20 and the evaporation part 40 and can isolate two regions of the sputter part 20 and the evaporation part 40 from each other.

The gate valve 120 can be a common slide gate. The gate valve 120 may be suitably automatically opened/closed by a controller (not shown) and interwork with the progress of a substrate transfer and deposition process.

The thermal processing part 60 is a part of performing a thermal processing process for stabilizing a light absorption layer deposited on the top surface of the substrate 100 in the deposition part 50. As illustrated, the thermal processing part 60 is connected and installed at a rear end of the evaporation part 40.

The thermal processing part 60 heats the substrate 100 completing the deposition of the light absorption layer, in a vacuum state at a temperature of about 400° C. to 600° C. during a predetermined time.

A gate valve 130 for region isolation can be installed between the thermal processing part 60 and the evaporation part 40. A transfer means 112 is installed at a low side of the thermal processing part 60 and works interworking with the transfer means 111 of the evaporation part 40.

The thermal processing part 60 may install a separate vacuum pump, or may connect and use the vacuum pump 43 of the evaporation part 40.

The thermal processing part 60 can be a high-speed thermal processing equipment such as a Rapid Thermal Process (RTP) equipment using a halogen lamp. However, desirably, the thermal processing part 60 is a low-speed thermal processing chamber for sequentially increasing a heating temperature from a low temperature to a high temperature and minimizing a thermal impact on the substrate 100.

A buffer layer deposition part 70 can be connected and installed at a rear end of the thermal processing part 60.

The buffer layer deposition part 70 is apart of forming a buffer layer between a light absorption layer of a CIGS solar cell and a transparent conductive film (i.e., a Transparent Conductive Oxide (TCO) layer). In a high vacuum atmosphere (about 1.0E-6 to 1.0E-7 Torr), the buffer layer deposition part 70 laminates and forms the buffer layer on a top surface of the light absorption layer of the substrate 100 using a sputter unit 75.

The buffer layer deposition part 70 performs a process under a similar environment condition to that of the sputter part 20 and thus, includes a transfer means 113 transferring the substrate 100 and a vacuum pump 73.

A gate valve 140 for region isolation is installed even in a connection part between the thermal processing part 60 and the buffer layer deposition part 70.

However, the sputter unit 75 of the buffer layer deposition part 70 uses a sputter target 72 of zinc sulfide (ZnS), indium sulfide (InS), or cadmium sulfide (CdS).

In conclusion, the present invention can continuously deposit the light absorption layer and the buffer layer on the substrate 100 by sequentially connecting and installing the substrate loading zone 10, the sputter part 20, the evaporation part 40, the thermal processing part 60, and the buffer layer deposition part 70 to interwork each other within one integration chamber 300 and connecting and installing the transfer means 110, 111, 112, and 113 from a front end of the integration chamber 300 to a rear end.

The transfer means 110, 111, 112, and 113 can be transfer rollers or conveyor units.

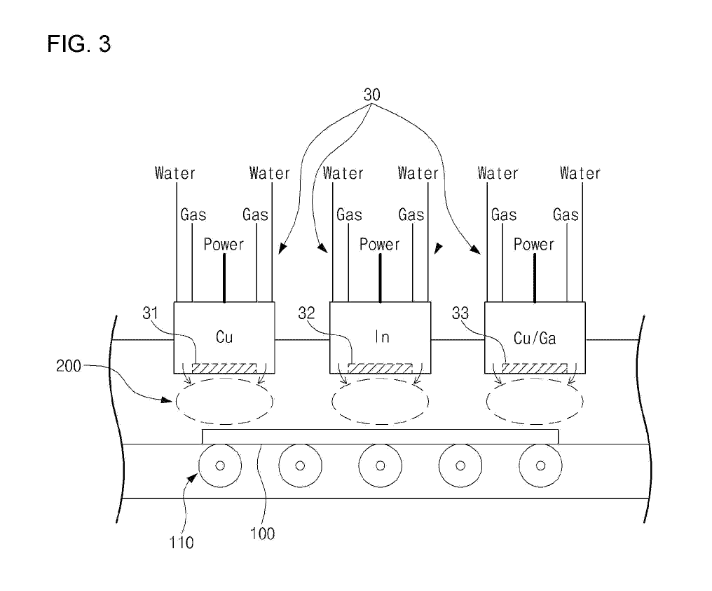

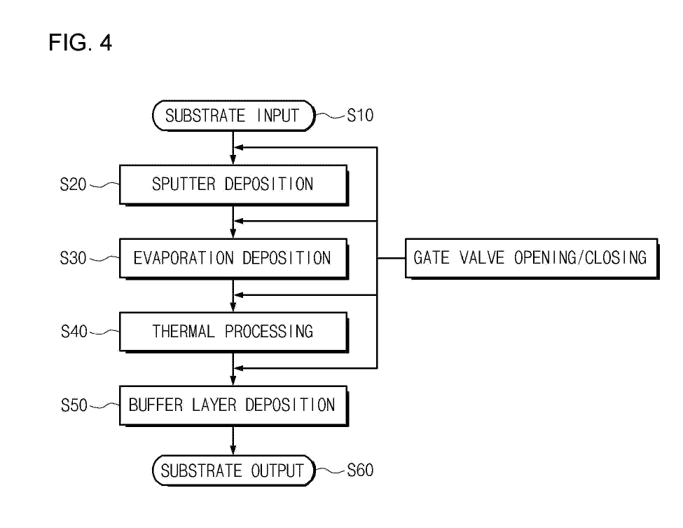

An operation process of an in-line system for manufacturing a solar cell according to the present invention is described below with reference to FIGS. 3 and 4.

FIG. 3 is a partial side diagram illustrating an operation state of the sputter part 20. FIG. 4 is a flow diagram illustrating an operation process of the present invention.

As illustrated in FIG. 4, an operation process of the present invention is sequentially carried out through substrate input (S10), sputter deposition (S20), evaporation deposition (S30), thermal processing (S40), buffer layer deposition (S50), and substrate output (S60).

The substrate input (S10) is that the substrate 100 preheated in the substrate loading zone 10 is inputted to the deposition part 50. The sputter deposition (S20) is that each sputter unit 30 deposits copper (Cu), indium (In), and copper/gallium (Cu/Ga) elements on the top surface of the substrate 100 in the sputter part 20.

At this time, if the substrate 100 fully enters the sputter part 20, the gate valve (not shown) is closed to isolate the substrate loading zone 10 from the sputter part 20.

The sputter deposition (S20) is that the deposition of copper (Cu), indium (In), and copper/gallium (Cu/Ga) is sequentially or simultaneously achieved on the substrate 100. As illustrated in FIG. 3, each sputter unit 30 down-jets a reaction gas along a circumference of sputter targets 31, 32, and 33. By high voltage, the jetted reaction gas is converted into a plasma state 200 on the top surface of the substrate 100.

At this time, positive (+) ions of the plasma state 200 are accelerated to collide with the sputter targets 31, 32, and 33 each forming a cathode. By the collision, copper (Cu), indium (In), and copper/gallium (Cu/Ga) elements of the respective sputter targets 31, 32, and 33 are jumped out and are deposited on the top surface of the substrate 100.

If the deposition is completed, the gate valve 120 of the rear end of the sputter part 20 is opened between the sputter part 20 and the evaporation part 40 and enables the substrate 100 to enter the evaporation part 40. After that, the gate valve 120 is again closed between the sputter part 20 and the evaporation part 40.

The evaporation deposition (S30) is that the evaporation part 40 deposits selenium (Se) on the top surface of the substrate 100. As illustrated in FIG. 2, the evaporation part 40 deposits the selenium particles 250 on the top surface of the substrate 100 by heating the storage container 46 of the selenium evaporator 45, evaporating the selenium particles 250, and forcibly diffusing an evaporated selenium gas to the top surface of the substrate 100 by means of a carrier gas supplied through the carrier gas supply line 48.

After that, the thermal processing process (S40) is performed in the thermal processing part 60. After that, the substrate 100 is transferred to the buffer layer deposition part 70 and the buffer layer deposition process (S50) is carried out.

At this time, the gate valve 130 is opened/closed to transfer the substrate 100 and also, isolates the thermal processing part 60 from the buffer layer deposition part 70.

The buffer layer deposition (S50) is carried out in the same method as that of the light absorption layer deposition of the sputter part 26.

Finally, the substrate 100 completing the deposition of the light absorption layer and the buffer layer as above is outputted (S60) outside the integration chamber 300 for the sake of a subsequent process.

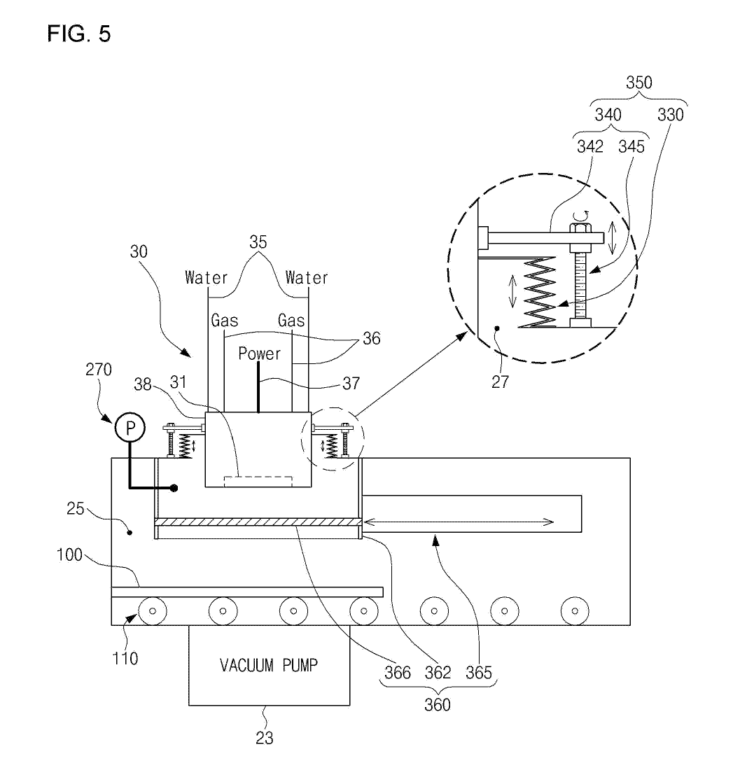

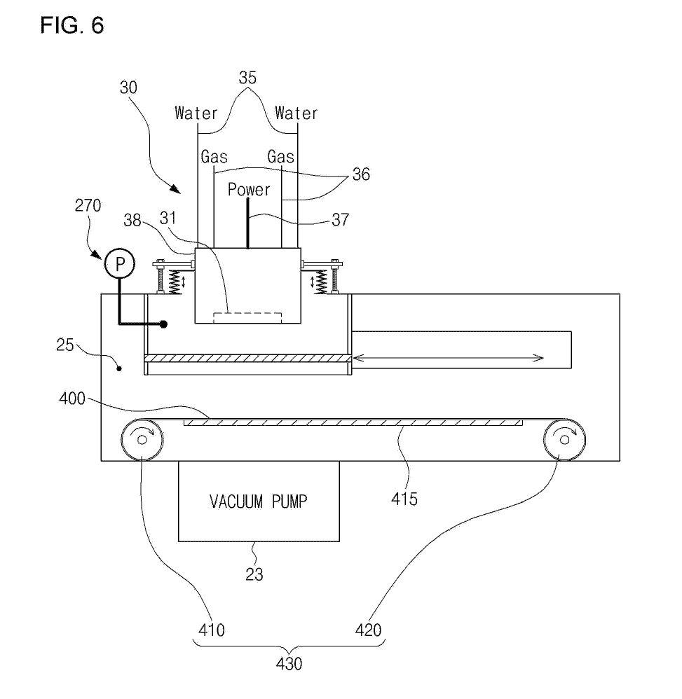

A sputter unit 30 of a sputter part 20 according to another exemplary embodiment of the present invention is described below with reference to FIGS. 5 and 6.

FIGS. 5 and 6 illustrate the sputter units 30 according to another exemplary embodiment of the present invention, respectively.

As illustrated in FIG. 5, a vacuum separation means 360 is installed in the sputter unit 30.

FIG. 5 illustrates that one sputter unit 30 is installed in a vacuum chamber 25, but this does not intend to limit the scope of the present invention. The vacuum separation means 360 can be installed, respectively, in a plurality of sputter units 30 in which sputter targets 31, 32, and 33 are installed as illustrated in FIG. 1. By doing so, the light absorption layer can be sequentially continuously deposited on the substrate 100 within one vacuum chamber 25.

An elevating means 350 is installed at an outer side surface of the sputter unit 30, and makes the sputter unit 30 ascend/descend to make a spaced distance between the sputter target 31 and the substrate 100 controllable.

The elevating means 350 is to suitably control the spaced distance between the sputter target 31 and the substrate 100 correspondingly to the consumption of the sputter target 31 following the deposition process performance. The elevating means 350 includes a bellows 330 and a control part 340.

The bellows 330 has a crease formed on an outer circumference surface and making its contraction or expansion possible. The bellows 330 is coupled at its one end to an outer circumference surface of a sputter gun 38, and is coupled at the other end to an upper part of the vacuum chamber 25.

The bellows 330 is coupled at its top end along the whole outer circumference surface of the sputter gun 38, and is coupled at its bottom end along a circumference of a through-hole 27 provided in the upper part of the vacuum chamber 25.

Desirably, the bellows 330 is detachably coupled to the upper part of the vacuum chamber 25 considering replacement of the sputter target 31.

The bellows 330 is installed to isolate its internal space from the external and also, communicate its internal space with the internal of the vacuum chamber 25.

The control part 340 supports and fixes the sputter gun 38 to a predetermined position. The control part 340 includes a support bar 342 and a control bar 345.

The support bar 342 is formed in plural on an outer circumference surface of the sputter gun 38. The support bar 342 is installed and positioned at an upper part of the bellows 330. The support bar 342 is coupled at one end to the outer circumference surface of the sputter gun 38, and is protruded outwards at the other end.

The support bar 342 is coupled at the other end to a top end of the control bar 345.

The control bar 345 is installed standing up and coupled at its top end to the support bar 342, and is coupled at the other end to the upper part of the vacuum chamber 25. The control bar 345 is installed to make up/down height control possible.

That is, the control bar 345 passes at its top end through the end of the support bar 342 and is rotatably coupled to the end of the support bar 342. The control bar 345 is installed to support the support bar 342. The control bar 345 is screw-coupled at its bottom end to the upper part of the vacuum chamber 25 and controls its coupling depth by rotation, thereby controlling a position of the support bar 342 in an up/down direction and making the sputter unit 30 ascend and descend.

However, the control bar 345 is not limited to the screw coupling, but may make the sputter unit 30 ascend and descend using a hydraulic or pneumatic cylinder or may use lifts of various forms using a gear, a chain, etc. other than the hydraulic or pneumatic cylinder.

Accordingly, if the sputter unit 30 ascends and descends using the control part 340, the bellows 330 is contracted or expanded correspondingly to this. By doing so, irrespective of the ascent or descent of the sputter unit 30, the bellows 330 can isolate the internal of the vacuum chamber 25 from the external, and maintain a vacuum state.

The vacuum separation means 360 is installed on an inner and upper surface of the vacuum chamber 25.

The vacuum separation means 360 is installed to open/close an installation space of the sputter unit 30 and isolate the installation space of the sputter unit 30 within the vacuum chamber 25. The vacuum separation means 360 includes a barrier 362 and a gate valve 365.

The barrier 362 is coupled and down-extended at its top end to an inner upper surface of the vacuum chamber 25. The barrier 362 is of a rectangular or cylindrical form, and is installed along a circumference of the sputter gun 38.

The barrier 362 is installed to partition an installation space of the sputter gun 38 within the vacuum chamber 25. So, as illustrated, the sputter gun 38 is positioned at a center of the barrier 362.

Also, a vacuum pump 270 is installed at one side of the barrier 362.

The vacuum chamber 270 plays a role of converting the internal space of the barrier 362 into a vacuum state in a state where the internal space of the barrier 362 is closed by the gate valve 365 described below.

The gate valve 365 is installed at one side of the barrier 362. The gate valve 365 has a slidable opening/closing plate 366 for opening/closing a lower part of the barrier 362 and isolating the internal space of the barrier 362 from the internal space of the vacuum chamber 25.

The gate valve 365 can be a common slide gate capable of sealing a passage of fluid and blocking or passing a flow of fluid. The gate valve 365 may be suitably adjusted by a controller (not shown) to interwork with the deposition process progress.

FIG. 6 illustrates a substrate transfer means of a sputter part 20 according to another exemplary embodiment of the present invention. As illustrated in FIG. 6, the substrate transfer means can be a roll-to-roll unit 430.

The exemplary embodiment of FIG. 6 is the same as the exemplary embodiment of FIG. 5 excepting the substrate transfer means and thus, only a modified construction is described below.

The exemplary embodiment of FIG. 6 uses a substrate 400 of flexible polymer material. As illustrated in FIG. 6, the roll-to-roll unit 430 is installed within the vacuum chamber 25 and is capable of continuously unwinding and simultaneously winding the substrate 400.

The roll-to-roll unit 430 is rotatably installed within the vacuum chamber 25 such that the flexible substrate 400 can be continuously transferred. The roll-to-roll unit 430 includes an unwinder roll 410 and a rewinder roll 420.

The unwinder roll 410 and the rewinder roll 420 are installed to face each other at both sides of the vacuum chamber 25.

The unwinder roll 410 is a part of continuously unwinding the substrate 400 wound on its outer circumference surface and sending the substrate 400 to the rewinder roll 420. The rewinder roll 420 plays a role of receiving a forward of the substrate 400 unwound from the unwinder roll 410, and again continuously winding the substrate 400 on its outer circumference surface.

The unwinder roll 410 and the rewinder roll 420 each can be comprised of rollers of metal material having a suitable diameter according to the environment or condition of a deposition process, and can continuously transfer the substrate 400 at a predetermined speed by means of a separate driving means (not shown).

The unwinder roll 410 may include a heating means for preheating the substrate 400 upon process need.

The heating means can be installed within the unwinder roll 410, and may be a common heating line arranged and installed.

The roll-to-roll unit 430 includes a plurality of guide rollers for guiding the substrate 400, besides the unwinder roll 410 and the rewinder roll 420. By doing so, the roll-to-roll unit 430 can secure the easiness of being capable of variously forming a transfer path of the substrate 400 within the vacuum chamber 25 using the guide rollers and variously arranging the sputter target 31 of the sputter unit 30 according to a transferred position of the substrate 400.

A substrate support 415 can be installed in the roll-to-roll unit, 430 and supports a bottom surface of the substrate 400 transferred.

Accordingly, the substrate 400 is continuously unwound and wound by the roll-to-roll unit 430 while a continuous sputter deposition process is performed.

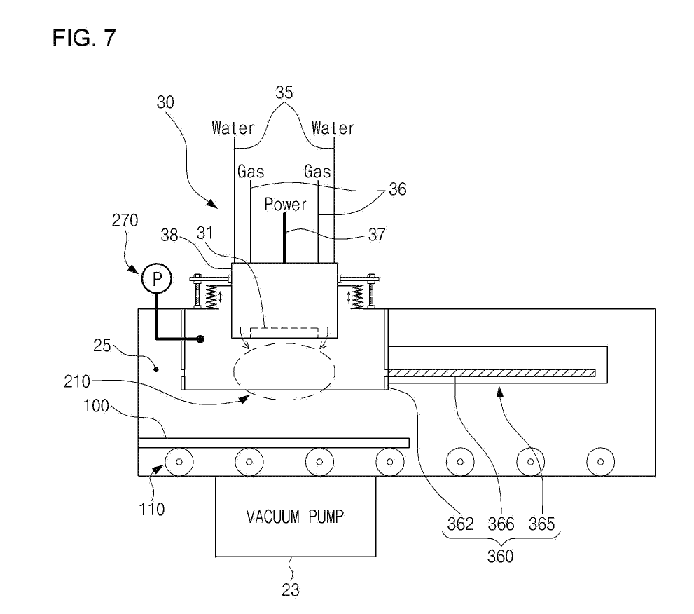

An operation process of the exemplary embodiment of FIG. 5 is described below in detail with reference to FIG. 7.

FIG. 7 is an operation state diagram illustrating an operation process of the sputter unit 30 of FIG. 5.

As illustrated in FIG. 7, if the substrate 100 is loaded within the vacuum chamber 25 by the transfer means 110, the sputter target 31 faces the top surface of the substrate 100, and the sputter unit 30 down-jets a reaction gas along a circumference of the sputter target 31. At this time, the jetted reaction gas is converted into a plasma state 210 on the top surface of the substrate 100 by a high voltage of a power source 37.

At this time, positive (+) ions of a plasma state 210 are accelerated and collide with the sputter target 31 forming a cathode. By the collision, molybdenum (Mo), copper (Cu), indium (In), or copper/gallium (Cu/Ga) elements of the sputter target 31 are jumped out and deposited on the top surface of the substrate 100, thereby performing a deposition process.

At this time, the gate valve 360 maintains a state of opening the barrier 362.

In case that the sputter target 31 is consumed following the progress of the deposition process and thus a control of a spaced distance between the top surface of the substrate 100 and a bottom surface of the sputter target 31 is needed, the control can be carried out to maintain the optimum distance by moving up/down the sputter gun 31 using the elevating means 350.

Also, the replacement of the sputter target 31 is achieved by sealing the barrier 362 using the gate valve 365, isolating an internal space of the vacuum chamber 25 from an internal space of the barrier 362, detaching the sputter unit 30, and replacing the sputter target 31 with a new one.

If the replacement of the sputter target 31 is completed, the sputter unit 30 is again coupled to the vacuum chamber 25 and then, the internal space of the bellows 330 and barrier 362 is converted into a vacuum state using the vacuum pump 270 installed in the barrier 362.

After that, the barrier 362 is opened using the gate valve 365 and then, the deposition process is again performed.

Accordingly, the present invention sequentially connects, installs, and makes a substrate loading zone 10, a sputter part 20, an evaporation part 40, a thermal processing part 60, and a buffer layer deposition part 70 in line with each other in one integration chamber 300, thereby being capable of obtaining an effect of increasing a process efficiency resulting from an increase of process continuity and an improvement of process speed, making easy the common use of an equipment such as a vacuum pump 23, etc., simplifying a layout of a solar cell manufacturing line, and making an efficient management of a line possible.

Also, the present invention can simply and conveniently control the spaced distance between the sputter target 31 and the substrate 100 or 400 even in course of deposition process performance without doing damage to the vacuum state of the vacuum chamber 25 using the elevating means 350, and can vacuum-isolate the installation space of the sputter unit 30 from the internal space of the vacuum chamber 25 using the vacuum separation means 360, thereby making replacement of the sputter target 31 possible without doing damage to the vacuum state of the whole vacuum chamber 25, improving process efficiency, and improving deposition quality.

As described above, the present invention has the following effects. The first is to increase productivity through the improvement of a process speed and a process efficiency by increasing a continuity of a process through an in-line deposition process line. The second is to make a reduction of an equipment cost and an efficient management of a manufacturing line possible by making the common use of a like equipment related to a vacuum chamber or thermal processing chamber possible and simplifying the whole layout. The third is to reduce a replacement time of a sputter target and a replacement cost, and remarkably reduce a deposition cost and a manufacturing cost. The fourth is to simply and conveniently control a spaced distance between the sputter target and a substrate, and greatly reduce a substrate error rate through the improvement of a deposition quality.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. An in-line system for manufacturing a solar cell, the system comprising:
a substrate loading zone for inputting a substrate;
a deposition part for sequentially continuously depositing a light absorption layer on a top surface of the substrate; and
a thermal processing part for thermally processing the substrate transferred from the deposition part,
wherein the substrate loading zone and the thermal processing part are sequentially installed in a partitioned internal space of one integration chamber, each transfer means transferring the substrate is sequentially connected and installed such that the substrate can be continuously transferred while being processed within one integration chamber.

2. The in-line system of claim 1, wherein the transfer means comprises conveyor units installed at lower parts of the substrate loading zone, the deposition part, and the thermal processing part, respectively, and being capable of sequentially continuously transferring the substrate.

3. The in-line system of claim 1, wherein the substrate loading zone further comprises a preheating means for preheating the substrate.

4. The in-line system of claim 1, wherein the deposition part comprises:
a sputter part for depositing copper (Cu), indium (In), and gallium (Ga) on the top surface of the substrate; and
an evaporation part for laminating and forming selenium (Se) on the top surface of the substrate.

5. The in-line system of claim 4, wherein the sputter part comprises a plurality of sputter units arranged and installed along a transfer direction of the substrate, and
wherein the sputter unit installs a sputter target formed of any one of copper (Cu), indium (In), and gallium (Ga) or a combination of two or more and facing the top surface of the substrate.

6. The in-line system of claim 4, wherein the deposition part comprises an automatic opening/closing gate valve for isolating regions of the sputter part and the evaporation part from each other.

7. The in-line system of claim 1, wherein the thermal processing part is comprised of a low-speed thermal processing part for continuously increasing a heating temperature from a low temperature to a high temperature and reducing a thermal impact applied to the substrate.

8. The in-line system of claim 1, wherein a buffer layer deposition part is connected and installed at a rear end of the thermal processing part, and laminates and forms a buffer layer on a top surface of the substrate.

9. The in-line system of claim 8, wherein automatic opening/closing gate valves are installed in connection parts between the deposition part and the thermal processing part, and between the thermal processing part and the buffer layer deposition part, respectively.

10. The in-line system of claim 5, wherein the deposition part comprises a vacuum separation means for opening and closing an installation space of the sputter unit and isolating the installation space of the sputter unit within a vacuum chamber of the deposition part.

11. The in-line system of claim 10, wherein the vacuum separation means comprises:
a barrier down-extended from an upper surface of the internal of the vacuum chamber of the deposition part; and
a gate valve for opening/closing a lower part of the barrier,
whereby the installation space of the sputter unit is partitioned within the vacuum chamber of the deposition part.

12. The in-line system of claim 10, wherein the deposition part further comprises an elevating means for making the sputter unit ascend and descend and making controllable a spaced distance between the sputter target provided in the sputter unit and the substrate.

13. The in-line system of claim 12, wherein the elevating means comprises:
a bellows coupled at its one end to an outer circumference surface of the sputter unit, and coupled at the other end to the upper surface of the vacuum chamber of the deposition part; and
a control part protruded from an outer circumference surface of the sputter unit and coupled to the upper surface of the vacuum chamber, and making a height control possible.

14. The in-line system of claim 13, wherein the control part comprises:
a support bar coupled at its one end to the outer circumference surface of the sputter unit; and
a control bar coupled at its top end to the other end of the support bar and coupled at its bottom end to an upper part of the vacuum chamber, and installed standing up to make an up/down height control of the support bar possible.

15. The in-line system of claim 1, wherein the transfer means is comprised of a roll-to-roll unit comprising an unwinder roll and a rewinder roll and capable of continuously unwinding and simultaneously winding the substrate.
